(19) United States
(12) Patent Application Publication
(10) Pub. No.: US 2022/0406660 A1
(43) Pub. Date: Dec. 22, 2022

(54) ELEMENT CHIP MANUFACTURING METHOD AND SUBSTRATE PROCESSING METHOD

(71) Applicant: Panasonic Intellectual Property Management Co., Ltd., Osaka (JP)

(72) Inventors: Shogo OKITA, Hyogo (JP); Hidehiko KARASAKI, Hyogo (JP); Hidefumi SAEKI, Osaka (JP); Atsushi HARIKAI, Osaka (JP)

(21) Appl. No.: 17/806,367

(22) Filed: Jun. 10, 2022

(30) Foreign Application Priority Data
Jun. 16, 2021 (JP) 2021-100492

(51) Int. Cl. H01L 21/78; H01L 21/268

(52) U.S. Cl. CPC H01L 21/78; H01L 21/268

(57) ABSTRACT

An element chip manufacturing method includes a step of preparing a substrate including a semiconductor layer and a wiring layer formed on the semiconductor layer and having a plurality of element regions and a dicing region defining the element regions, a laser grooving step of irradiating a laser beam to the wiring layer at the dicing region, to form an aperture exposing the semiconductor layer, and an individualization step of etching the semiconductor layer exposed from the aperture, with plasma, to divide the substrate into a plurality of element chips. The laser grooving step including a step of irradiating a first laser beam, to form a first groove exposing the semiconductor layer in the dicing region, and a step of irradiating a second laser beam, with a beam center positioned outside a side wall of the first groove, to widen the first groove into the aperture.

### CROSS REFERENCE TO RELATED APPLICATION

The present application is based on and claims priority under 35 U.S.C. § 119 with respect to the Japanese Patent Application No. 2021-100492 filed on Jun. 16, 2021, of which entire content is incorporated herein by reference into the present application.

### TECHNICAL FIELD

The present invention relates to an element chip manufacturing method including a step of dicing a substrate including a semiconductor layer with plasma.

### BACKGROUND

As a method of dicing a semiconductor wafer including a plurality of integrated circuits, Patent Literature 1 (JP2015-519732A) proposes a method that includes: forming a protective layer for covering integrated circuits above the semiconductor wafer; patterning gaps in the protective layer to form a mask; and etching the semiconductor wafer through the gaps. The literature suggests patterning the protective layer by multi-step laser scribing, and using a Gaussian beam pass or a top-hat beam pass for the laser.

In recent years, as a method of manufacturing element chips by dicing a substrate having a wiring layer and a semiconductor layer, there has been developed a technique of etching the semiconductor layer by forming a groove-like aperture (gap) called a street in the wiring layer along a dicing region, and etching the semiconductor layer exposed from the aperture with plasma.

When a Gaussian beam or a top-hat beam as suggested by Patent Literature 1 is used for scribing along the dicing region, the beam intensity is reduced in the vicinity of the side walls on both sides of the aperture, as compared to at the bottom of the aperture. As a result, the energy density of the beam in the vicinity of the side walls becomes insufficient, and the melted matter of the wiring layer (hereinafter sometimes referred to as “debris”) tends to adhere to the side walls. When the debris adheres to the side walls, this may cause streaks on the chip cross section in the subsequent plasma etching process, leading to a decreased die strength in some cases.

On the other hand, in order to suppress the adhesion of debris to the side walls, when a beam whose energy density in the vicinity of the side walls is sufficiently high is used, the energy density becomes higher than necessary at the bottom of the aperture, and the heat-affected zone expands, causing damage on the chip (semiconductor layer) in some cases.

### SUMMARY

In view of the above, one aspect of the present invention relates to an element chip manufacturing method, including: a step of preparing a substrate including a semiconductor layer having a first principal surface and a second principal surface and a wiring layer formed on the semiconductor layer on the first principal surface side, the substrate having a plurality of element regions and a dicing region defining the element regions; a laser grooving step of irradiating a laser beam from the first principal surface side to the wiring layer at the dicing region, to form an aperture exposing the semiconductor layer in the dicing region; and an individualization step of etching the semiconductor layer exposed from the aperture, with plasma, until reaching the second principal surface, to divide the substrate into a plurality of element chips having the element regions, the laser grooving step including a groove forming step of irradiating a first laser beam, to form a first groove exposing the semiconductor layer in the dicing region, and a widening step of irradiating a second laser beam, with a beam center positioned outside a side wall in a width direction of the first groove formed in the groove forming step, to widen the first groove into the aperture.

Another aspect of the present invention relates to a substrate processing method for forming an aperture at a predetermined region on a substrate including a semiconductor layer having a first principal surface and a second principal surface and a wiring layer formed on the semiconductor layer on the first principal surface side, the aperture being formed to expose the semiconductor layer, the method including: an irradiation step of irradiating a laser beam from the first principal surface side to the wiring layer at the predetermined region; the irradiation step including a groove forming step of irradiating a first laser beam, to form a first groove exposing the semiconductor layer in the predetermined region, and a widening step of irradiating a second laser beam, with a beam center positioned outside a side wall in a width direction of the first groove formed in the groove forming step, to widen the first groove into the aperture.

According to the present invention, when an aperture is formed in the wiring layer by laser scribing, it is possible to form an aperture with less adhesion of debris on the side walls, while suppressing the damage on the semiconductor layer.

### BRIEF DESCRIPTION OF THE DRAWINGS

FIGS. 1A to 1D are schematic process cross-sectional views illustrating an element chip manufacturing method according to one embodiment of the present disclosure.

FIGS. 2A and 2B are schematic process cross-sectional views illustrating an element chip manufacturing method according to one embodiment of the present disclosure, which show another example of the groove forming step shown in FIG. 1B.

FIG. 3 is a schematic representation of the configuration of an example of an apparatus for outputting a laser beam.

FIG. 4 is a schematic representation of an example of a plasma processing apparatus used in a dicing step.

FIG. 5A is a top view of a conveying carrier supporting a substrate, and FIG. 5B is a cross-sectional view thereof taken along a line Y-Y.

### DETAILED DESCRIPTION

An element chip manufacturing method according to an embodiment of the present disclosure includes a step of preparing a substrate including a semiconductor layer having a first principal surface and a second principal surface and a wiring layer formed on the semiconductor layer on the first principal surface side. The substrate has a plurality of element regions and a dicing region (street) defining the element regions. The wiring layer may include a circuit layer and a resin layer protecting a surface of the circuit layer. Usually, the circuit layer contains a metal material, and the resin layer contains a resin material. The dicing region is provided linearly in a predetermined pattern, on the first principal surface side of the substrate.

The semiconductor layer is constituted of, for example, silicon (Si), gallium arsenide (GaAs), gallium nitride (GaN), silicon carbide (SiC), and the like.

The wiring layer usually includes a circuit layer, and a resin layer protecting a surface of the circuit layer. The circuit layer contains, for example, a low-k (low dielectric constant) material, a copper (Cu) wiring layer, a metal material, an electrically insulating film (e.g., silicon dioxide, silicon nitride), lithium tantalate (LiTaO₃), lithium niobate (LiNbO₃), and the like. The resin layer contains, for example, a thermosetting resin such as polyimide, a photoresist such as phenol resin, a water-soluble resist such as acrylic resin, and the like.

The element chip manufacturing method includes a laser grooving step of irradiating a laser beam from the first principal surface side to the wiring layer at the dicing region, to form an aperture (gap) exposing the semiconductor layer in the dicing region. This laser grooving step is also called a scribing process or a laser scribing process. The aperture is usually formed like a groove along the linear dicing region. The width direction of the dicing region is synonymous with the direction of the width of the aperture (gap) formed like a groove, and is the direction orthogonal to the length direction of the street. For effective utilization of the substrate, a smaller width of the groove-like aperture is more preferable. The aperture can be more easily narrowed in width as the verticality of the side surfaces of the wiring layer on both sides of the aperture is enhanced.

In the laser grooving step, first, a groove forming step of irradiating a first laser beam to the wiring layer at the dicing region, to form a first groove exposing the semiconductor layer is performed. The width of the first groove is preferably smaller than that of the dicing region. At this time, debris derived from the wiring layer may adhere to the side walls of the first groove. The debris, however, will be removed by the subsequent widening step. Given that the width of the dicing region is denoted by W₀, a width W₁ of the first groove may be 50% to 90% of the W₀. A beam diameter D₁ of the first laser beam is determined according to the W₁.

Next, a widening step of irradiating a second laser beam to the side walls of the first groove formed in the groove forming step is performed, to widen the first groove into the aperture. In the widening step, the second laser beam is irradiated, with the beam center of the second laser beam positioned outside a side wall in the width direction of the first groove. This can widen the first groove into the aperture, and remove the debris adhering to the side walls of the first groove. As a result, the aperture with less adhesion of debris can be formed. Furthermore, since it is not necessary to increase the energy density of the first laser beam more than necessary at the center of the bottom of the first groove, the expansion of the heat-affected zone due to laser irradiation is suppressed. Therefore, damage to the semiconductor layer is also suppressed. The beam diameter D₂ of the second laser beam may be determined such that, for example, D₁+2D₂ is 95% to 105% of the Wo.

In the widening step, the beam center of the second laser beam is positioned away from the side wall of the first groove toward the element region by, for example, ⅓ or more of the beam diameter of the second laser beam. The distance between the beam center of the second laser beam and the side wall of the first groove is, for example, ⅓ or more and 1 times or less of the beam diameter of the second laser beam, and preferably, ½ or more and ⅘ or less of the beam diameter of the second laser beam.

Here, the beam diameter means the diameter of the circle that contains 86% of the beam power (D86 diameter).

The groove forming step may include a step of irradiating a third laser beam with a beam center positioned at an edge portion of the dicing region, to form a second groove as part of the first groove, and a step of irradiating a fourth laser beam with a beam center positioned inside from the edge portion of the dicing region, to expose the semiconductor layer on a side inner than the edge portion, so that the first groove is formed. The second groove formed by the third laser beam prevents a crack from extending into the element region due to the heat generated by the subsequent irradiation of the fourth laser beam. Furthermore, by forming the second groove in advance, the adhesion of debris due to the fourth laser beam is suppressed. The beam diameter D₃ of the third laser beam and the beam diameter D₄ of the fourth laser beam may be such that, for example, 2D₃+D₄ is 95% to 105% of the width W₁ of the first groove.

The laser grooving step is followed by an individualization step to divide the substrate. In the individualization step, the semiconductor layer exposed from the formed aperture is etched with plasma until reaching the second principal surface. The semiconductor layer at the element regions is masked with the wiring layer. Therefore, the semiconductor layer at the dicing region exposed from the aperture is etched with plasma. In this way, the substrate is divided into a plurality of element chips having the element regions.

When the verticality of the side surfaces of the wiring layers on both sides of the aperture is insufficient, in etching the semiconductor layer with plasma, the side walls of the formed element chips are disordered, and the die strength of the element chips tend to decrease. On the other hand, by improving the verticality of the side surfaces of the wiring layer to improve the quality of the aperture, the side walls of the semiconductor layer etched with plasma are less likely to be disordered, and high-quality element chips having excellent die strength can be obtained. Furthermore, as the verticality of the side surfaces of the wiring layer improves, the width of the groove-like aperture can be narrower (smaller), and the loss of the substrate can be reduced.

When plasma etching is utilized for individualization of the substrate, it is also necessary to pay attention to the contamination on the side walls and the bottom of the aperture or groove. For example, when the wiring layer includes a circuit layer and a resin layer protecting the circuit layer, with a laser beam having a Gaussian or a top-hat distribution whose intensity is restricted in order to reduce the processing damage on the semiconductor layer, a sufficient energy density for ablating the layer cannot be obtained at the beam end, and the resin becomes liquefied and round in shape due to surface tension, tending to cause a resin ball to adhere as debris, at the edge portions of the bottom of the aperture.

The resin ball will not be so problematic when the semiconductor layer is mechanically diced with a blade or the like. However, when the semiconductor layer is etched with plasma, the resin ball will be an obstacle to the reaction between the plasma and the semiconductor layer. As a result, the side walls of the semiconductor layer etched with plasma tend to be disordered, and the quality of the element chips deteriorates in some cases.

According to the method of the present disclosure, however, since the adhesion of the resin ball or debris to the aperture side walls is suppressed in the laser grooving step, in the subsequent individualization step, the disorder of the side walls of the semiconductor layer etched with plasma can be suppressed. For example, vertical streaks are suppressed from appearing on the side walls of the semiconductor layer etched with plasma. As a result, high-quality element chips having excellent die strength can be obtained. Furthermore, since the side surfaces of the semiconductor layer can be etched to be more nearly vertical, the width of the aperture (width of the dicing region) can be reduced.

The method of the present disclosure is not limited to the use for manufacturing element chips, and is applicable for forming an aperture by laser processing on a substrate having a semiconductor layer on which a wiring layer is formed. The substrate processing method of the present embodiment is for forming an aperture at a predetermined region on a substrate including a semiconductor layer having a first principal surface and a second principal surface and a wiring layer formed on the semiconductor layer on the first principal surface side, the aperture being formed to expose the semiconductor layer. The method includes an irradiation step of irradiating a laser beam from the first principal surface side to the wiring layer at the predetermined region. The irradiation step includes a groove forming step of irradiating a first laser beam, to form a first groove exposing the semiconductor layer in the predetermined region, and a widening step of irradiating a second laser beam, with a beam center positioned outside a side wall in a width direction of the first groove formed in the groove forming step, to widen the first groove into the aperture. In this way, it is possible to form an aperture with less adhesion of debris, while suppressing the damage to the semiconductor layer.

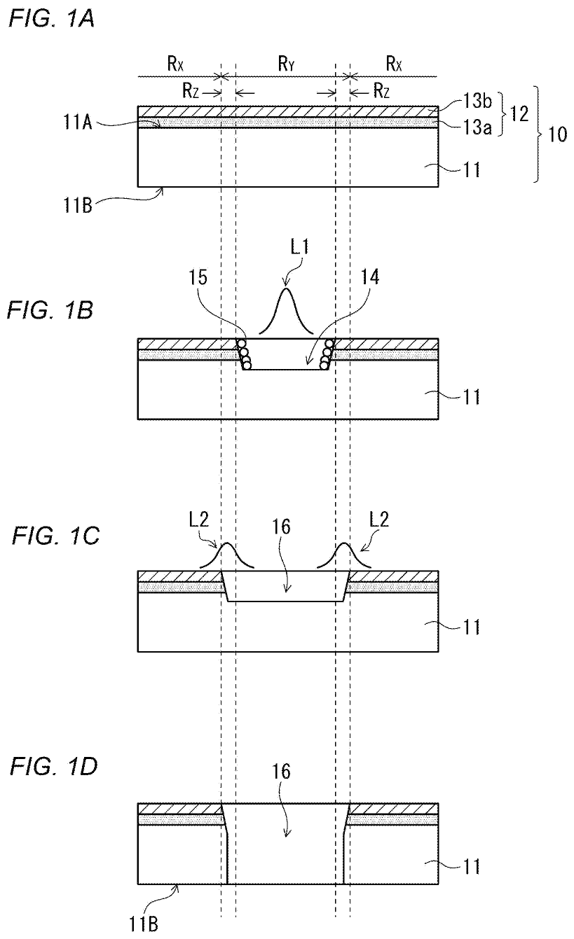

FIGS. 1A to 1D are schematic process cross-sectional views illustrating an element chip manufacturing method according to one embodiment of the present disclosure, which particularly show an example of the laser grooving step.

First, as shown in FIG. 1A, a substrate 10 is prepared (preparation step). The substrate 10 includes a semiconductor layer 11 having a first principal 11A and a second principal surface 11B, and a wiring layer 12 formed on the semiconductor layer 11 on the first principal surface 11A side. The wiring layer 12 includes, for example, a circuit layer 13a and a resin layer 13b protecting the circuit layer. The substrate 10 includes a plurality of element regions Rx and a dicing region Ry defining the element regions Rx.

Next, as illustrated in FIG. 1B, the first laser beam L1 is irradiated to the dicing region Ry, to form a first groove 14 (first step). The irradiation of the first laser beam L1 is performed until the semiconductor layer 11 is exposed, in the first groove 14. The first laser beam L1 may be a laser beam having a Gaussian distribution or a top-hat distribution. The laser beam having a top-hat distribution is a laser beam whose beam intensity is substantially constant within a predetermined range of the distance from the center of the beam. The intensity at the edge portions of the top-hat distribution (the shoulder portions where the intensity starts to drop sharply) is not significantly different from the intensity at the center, and is, for example, 90% to 98% of the intensity at the center. For the beam shaping to the top-hat distribution, any known technique, such as a diffractive optical element (DOE) and an aspherical beam shaper, can be used.

The irradiation of the first laser beam L1 is controlled such that the first groove 14 to be formed will not across the boundary between the element region Rx and the dicing region Ry, and a region Rz covered with the wiring layer 12 will be left at a boundary portion of the dicing region Ry in contact with the element region Rx. That is, the edge portion Rz of the dicing region Ry is kept covered with the wiring layer 12 even after the irradiation of the first laser beam L1.

The beam intensity of the first laser beam L1 can be controlled to a value at which damage to the underlying semiconductor layer 11 beneath the wiring layer 12 is sufficiently suppressed even at the irradiation position where the beam intensity reaches its maximum. In this case, a sufficient energy density for removing the wiring layer 12 by ablation cannot be obtained at the beam end, and debris 15 derived from the melted wiring layer may adhere to the side walls of the first groove 14.

Subsequently, as shown in FIG. 1C, the width of the first groove 14 is widened by irradiation of the second laser beam L2, into an aperture 16 (widening step). At this time, the irradiation of the second laser beam L2 is performed with the beam center of the second laser beam L2 positioned outside a side wall (e.g., within the boundary portion Rz) in the width direction of the first groove 14. In this way, at least part of the semiconductor layer at the edge portion the dicing region Ry is removed, and the debris 15 adhering to the side walls of the first groove 14 is also removed, and as a result, the aperture 16 with the side walls free of the debris 15 can be obtained.

The maximum value in the beam intensity distribution of the second laser beam L2 may be about the same as that of the first laser beam L1. The beam shape of the second laser beam L2 is not limited, but the beam intensity of the second laser beam L2 is preferably such that the width of the shoulder portion (e.g., the beam width at which the beam intensity is 50% or more and 90% or less of the maximum value) is small, and the beam intensity drops sharply with distance away from the center of the beam. The second laser beam L2 may be a laser beam having a Gaussian distribution.

The position of the beam center of the second laser beam L2 may be away from the side wall of the first groove 14 by a distance of, for example, ⅓ or more and 1 times or less of the beam diameter (D86 diameter) of the second laser beam, and preferably, ½ or more and ⅘ or less of the beam diameter of the second laser beam. The above distance may be, for example, 3 μm or more and 6.5 μm or less.

The spot shape of the first laser beam L1 and the second laser beam L2 is not limited. The spot shape is a cross-sectional shape perpendicular to the optical axis of the laser beam. The spot shape may be circular, elliptical, or polygonal.

The first laser beam L1 and/or the second laser beam L2 may be irradiated to the dicing region only once or more than once. By irradiating the laser beam separately more than once, the heat influence by laser on the surroundings can be reduced. Therefore, the damage by heat is less likely to occur on the side surfaces of the wiring layer on both sides of the aperture and on the semiconductor layer at the bottom of the aperture. The number of times of irradiation of the laser beam refers to the number of times of scanning of the laser beam to be scanned along the dicing region, and does not mean the number of pulses.

Subsequently, as shown in FIG. 1D, the semiconductor layer 11 exposed at the bottom of the aperture 16 is etched with plasma until reaching the second principal surface 11B (individualization step). As a result, the substrate 10 having a plurality of element regions is divided into a plurality of element chips each having a corresponding element region.

After forming the aperture 16 and before performing the individualization step, a step of cleaning the aperture 16 with plasma may be performed. This plasma is generated, usually, under conditions different from the plasma generated for etching the semiconductor layer 11 in the dicing region. Such a cleaning step is performed, for example, for the purpose of further reducing the residue caused by forming the aperture 16 by laser irradiation. This enables to perform high-quality plasma dicing.

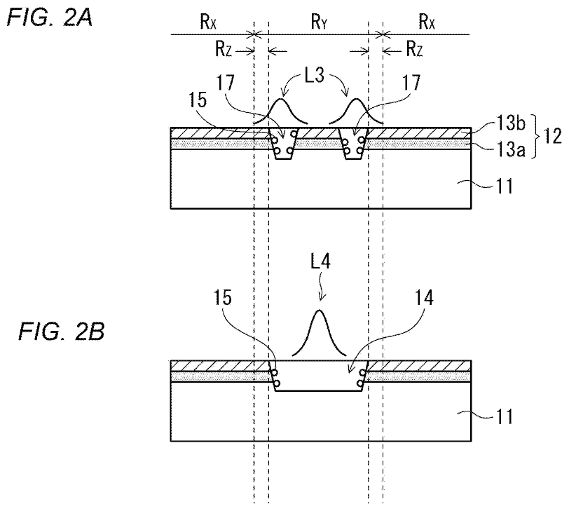

FIGS. 2A and 2B are schematic process cross-sectional views illustrating an element chip manufacturing method according to one embodiment of the present disclosure, which show another example of the groove forming step. The preparation step, the widening step, and the individualization step are similar to in FIGS. 1A, 1C, and 1D, respectively, and the description thereof will be omitted.

In the example shown in FIG. 2, the groove forming step includes a step of irradiating a third laser beam with the center of the beam center positioned at an edge portion of the dicing region Ry, to form a second groove (see FIG. 2A), and a step of irradiating a fourth laser beam, which is the first laser beam, with the center of the beam positioned inside from the edge portion of the dicing region Ry, to expose the semiconductor layer 11 on a side inner than the edge portion, so that the first groove 14 is formed (see FIG. 2B).

In the groove forming step, as shown in FIG. 2A, prior to forming the first groove 14, a third laser beam L3 is irradiated to the positions corresponding to the both ends of the first groove 14 to form second grooves 17. The second grooves 17 serve to prevent a crack from extending into the element region Ry due to the heat generated during laser irradiation, when forming the first groove 14. In this process, debris 15 derived from the wiring layer melted by the irradiation of the third laser beam L3 can adhere to the side walls of the second groove 17. However, the amount thereof is smaller than that caused by the irradiation of the first laser beam shown in FIG. 1B because the volume of the wiring layer to be removed in this process is small.

The width of the second groove 17 is, for example, 4μm or more and 10 μm or less. The irradiation of the third laser beam L3 is preferably performed until the semiconductor layer 11 is exposed within the second groove 17. However, the second groove 17 may have any depth as long as it has a function of preventing crack extension, and may be not so deep as to expose the semiconductor layer 11. The beam diameter of the third laser beam L3 is determined according to the width of the formed second groove 17. The beam intensity of the third laser beam L3 may be such that the maximum value in the beam intensity distribution is about the same as that of the first laser beam L1.

The edge portion at which the second groove 17 is formed is located nearer the element region Rx than the center of the dicing region, within the dicing region Ry. The distance from the center of the edge portion (center of the second groove 17) to the boundary between the element region Rx and the dicing region Ry may be, for example, 2% to 15% of the width of the dicing region Ry.

Subsequently, as shown in FIG. 2B, a fourth laser beam L4 is irradiated to remove the wiring layer in the region sandwiched between the second grooves 17, so that the first groove 14 is formed. By forming the second grooves 17 beforehand, the adhesion of debris due to the fourth laser beam L4 is suppressed. The debris adhering to the side walls in the step of forming the second grooves 17 is removed in the subsequent widening step (see FIG. 1C). The beam diameter and beam intensity of the fourth laser beam L4 may be about the same as those of the first laser beam L1.

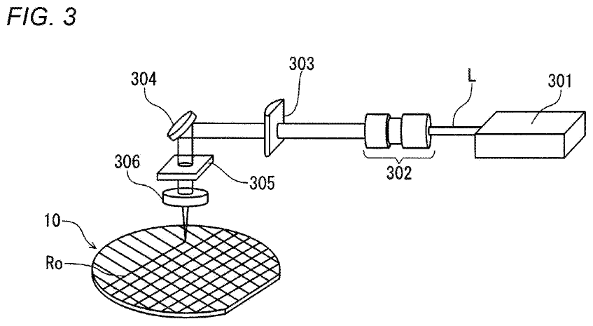

Next, a description will be given of an apparatus for performing the laser grooving step. The laser beam used in the laser grooving step can be obtained using, for example, an optical system as shown in FIG. 3. The optical system of FIG. 3 includes a laser oscillator 301, a zoom expander 302, a cylindrical lens 303 having a semicircular cross section, a bend mirror 304, a DOE 305, and a condenser lens 306. A laser beam L emitted from the laser oscillator 301, which has a Gaussian distribution in all directions, enters the zoom expander 302 having a collimating function. The zoom expander 302 adjusts the beam diameter of the laser beam L to an appropriate value for the DOE 305 which the laser beam transmitted through the cylindrical lens 303 enters. The laser beam L having a circular beam spot output from the zoom expander 302 is converted to have an elliptic beam spot by passing through the cylindrical lens 303, and incident on the bend mirror 304. The DOE 305 converts the spot shape of the laser beam into a rectangular shape. The converted laser beam enters the condenser lens 306, and then, irradiated to the substrate 10. The spot diameter of the laser beam output from the condenser lens 306 is condensed to, for example, 35 μm or less (preferably 20 μm or less) in the width direction of the dicing region, and is irradiated to the substrate (wiring layer) which is an object to be processed.

The DOE 305 can be equipped with a function of converting the spot shape of the laser beam into a desired shape. Furthermore, the DOE can be equipped with a function of converting the beam intensity distribution having a Gaussian distribution to a top-hat distribution.

The laser oscillator 301 is a pulse laser oscillator that emits a pulsed laser beam, and the mechanism for oscillating the laser beam L in a pulsed waveform is not limited. For example, it is possible to adopt a system of turning the beam output ON and OFF with a mechanical shutter, a system of pulse-controlling the excitation source of the laser beam L, a system of switching the beam output, and the like. The laser oscillation mechanism of the laser oscillator 301 is also not limited, and may be, for example, a semiconductor laser using a semiconductor as a laser oscillation medium, a gas laser using a gas, such as carbon dioxide (CO₂), as the medium, a solid laser using YAG, a fiber laser, and the like. The solid laser includes a wavelength-converted green laser and an ultraviolet laser.

The pulse width of the laser beam L irradiated to the substrate 10 is not particularly limited, but is preferably 500 nanoseconds or less, and more preferably 200 nanoseconds or less, in terms of reducing the heat influence. The wavelength of the laser beam L is also not limited, but is preferably in an ultraviolet region (wavelength: 200 to 400 nm) or a visible region with a relatively short wavelength (wavelength: 400 to 550 nm) because in this case the laser beam L is highly absorbed by the substrate 10. The oscillation frequency of the laser beam L is also not limited, but is, for example, 1 to 200 kHz. A higher oscillation frequency can increase the speed of processing.

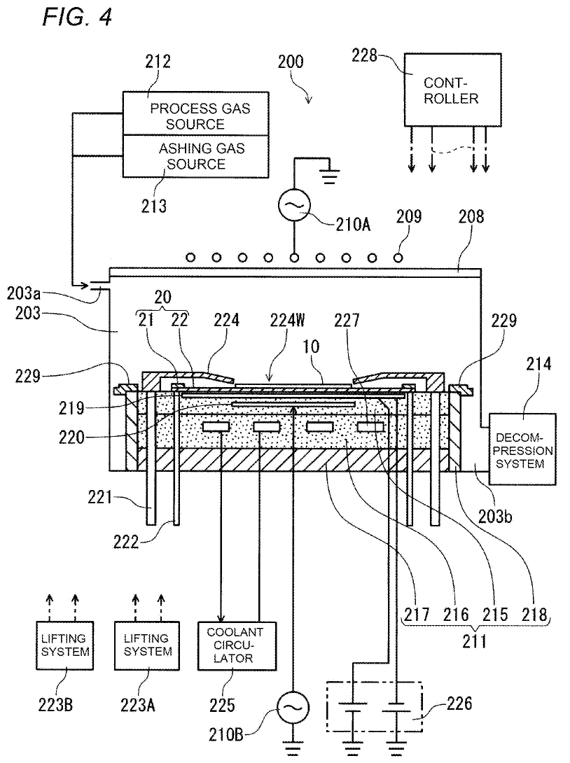

Next, a description will be given of a plasma processing apparatus used in the individualization step, with reference to FIG. 4. It is to be noted, however, that the plasma processing apparatus is not limited thereto.

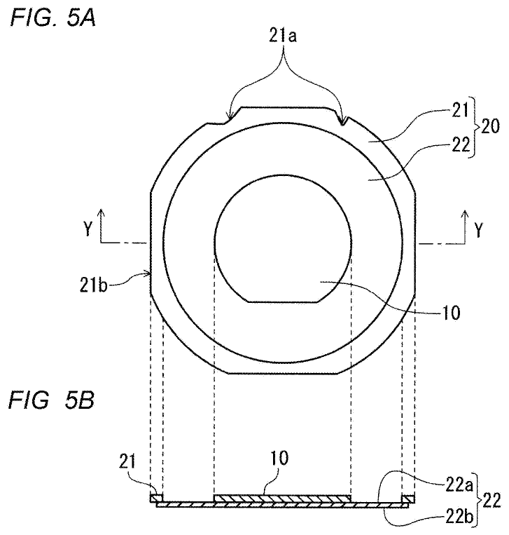

In view of the ease of handling, the individualization step is preferably performed while the substrate 10 is supported by a support member 22 as shown in FIG. 5. At this time, the second principal surface 11B side of the semiconductor layer 11 of the substrate 10 is brought into contact with the support member 22. Any material may be used for the support member 22. Especially when taking into consideration that the substrate 10 is diced while being supported by the support member 22, the support member 22 is preferably made of a flexible resin film, for easy picking up of element chips 10x. At this time, in view of the ease of handling, the support member 22 is fixed to the frame 21. In the following, the frame 21 and the support member 22 fixed to the frame 21 are collectively referred to as a conveying carrier 20. FIG. 5A is a top view of the conveying carrier 20 and the substrate 10 supported by the support member 22, and FIG. 5B is a cross-sectional view thereof taken along a line Y-Y. The support member 22 includes, for example, a surface having an adhesive (adhesive side 22a) and a surface having no adhesive (non-adhesive side 22b). The frame 21 may be provided with a notch 21a or a corner cut 21b for positioning.

A plasma processing apparatus 200 includes a vacuum chamber 203 having a processing space, and has a stage 211 in the processing space. The vacuum chamber 203 is provided with an inlet 203a for introducing gas and an outlet 203b for exhausting gas. The gas inlet 203a is configured to be connected selectively to one of a process gas source 212 and an ashing gas source 213. The gas outlet 203b is connected to a decompression system 214 having a vacuum pump for exhausting the gas within the vacuum chamber 203 to reduce the pressure therein.

On the stage 211, the substrate 10 held on the conveying carrier 20 is placed. The stage 211 is provided at its peripheral portion with a plurality of supports 222 configured to be driven to move up and down by a lifting system 223A. The conveying carrier 20 delivered into the vacuum chamber 203 is passed onto the supports 222, and placed on the stage 211.

Above the stage 211, a cover 224 having a window 224W for covering at least the frame 21 of the conveying carrier 20 and exposing the substrate 10 therefrom is disposed. The cover 224 is coupled with a plurality of lifting rods 221, and driven to move up and down by a lifting system 223B. The vacuum chamber 203 is closed at its upper part with a dielectric member 208, and an antenna 209 is disposed as an upper electrode, above the dielectric member 208. The antenna 209 is connected to a first high-frequency power source 210A.

The stage 211 includes an electrode layer 215, a metal layer 216, and a base table 217 disposed in this order from above, which are surrounded by an outer peripheral portion 218. An outer peripheral ring 229 for protection is disposed on the upper surface of the outer peripheral portion 218. Inside the electrode layer 215, an electrode part (ESC electrode) 219 for electrostatic adsorption, and a high-frequency electrode part 220 connected to the second high-frequency power source 210B are disposed. The ESC electrode 219 is connected to a DC power source 226. By applying a high-frequency power to the high-frequency electrode part 220, the etching step can be performed under application of a bias voltage. A coolant channel 227 for cooling the stage 211 is formed within the metal layer 216, and a coolant is circulated by a coolant circulator 225.

A controller 228 controls the operations of constituent elements of the plasma processing apparatus 200, including the first and second high-frequency power sources 210A and 210B, the process gas source 212, the ashing gas source 213, the decompression system 214, the coolant circulator 225, the lifting systems 223A and 223B, and the electrostatic chuck system.

The plasma is generated under conditions with which the semiconductor layer 11 of the substrate 10 is etched. The etching conditions may be determined appropriately according to the material of the semiconductor layer 11. When the semiconductor layer 11 is made of Si, a Bosch process can be adopted for etching the semiconductor layer 11 along the dicing region Ry. In the Bosch process, a protective film deposition step, a protective film etching step, and a Si etching step are sequentially repeated in this order, thereby to deepen the groove in the depth direction.

The protective film deposition step is carried out, for example, under the following conditions: while C₄F₈ is introduced as a raw material gas at a rate of 150 to 250 sccm, the pressure in the vacuum chamber 203 is controlled to 15 to 25 Pa, with the input power to the antenna 209 from the first high-frequency source 210A set at 1500 to 2500 W, and the input power to the high-frequency electrode part 220 from the second high-frequency power source 210B set at 0 W; the processing time is 5 to 15 seconds.

The protective film etching step is carried out, for example, under the following conditions: while SF₆ is introduced as a raw material gas at a rate of 200 to 400 sccm, the pressure in the vacuum chamber 203 is controlled to 5 to 15 Pa, with the input power to the antenna 209 from the first high-frequency source 210A set at 1500 to 2500 W, and the input power to the high-frequency electrode part 220 from the second high-frequency power source 210B set at 100 to 300 W; the processing time is 2 to 10 seconds.

The Si etching step is carried out, for example, under the following conditions: while SF₆ is introduced as a raw material gas at a rate of 200 to 400 sccm, the pressure in the vacuum chamber 203 is controlled to 5 to 15 Pa, with the input power to the antenna 209 from the first high-frequency source 210A set at 1500 to 2500 W, and the input power to the high-frequency electrode part 220 from the second high-frequency power source 210B set at 50 to 200 W; the processing time is 10 to 20 seconds.

By repeating the protective film deposition step, the protective film etching step, and the Si etching step under the conditions as above, the dicing region Ry can be etched vertically in the depth direction at a rate of approximately 10 μm/min. In generating the plasma, a plurality of kinds of raw material gases may be used in combination. In this case, a plurality of kinds of raw material gases may be introduced with a time lag into the vacuum chamber 203, or a plurality of kinds of raw material gases may be mixed and introduced into the vacuum chamber 203.

In this way, the substrate 10 is divided into a plurality of element chips 10x having the element regions Rx, while being supported by the support member 22. After the plasma dicing step is completed, the plurality of element chips 10x supported by the support member 22 are transferred to the pickup step. In the pickup step, the plurality of element chips 10x are detached from the support member 22.

The plasma dicing step may be followed by ashing or cleaning to remove the resin film remaining on the element chip 10x.

According to the element chip manufacturing method of the present invention, high-quality plasma dicing can be performed. The method is therefore useful as a method for manufacturing element chips from various substrates.

### [Reference Numerals]

10: substrate

10x: element chip
11: semiconductor layer
   11A: first principal surface
   11B: second principal surface
12: wiring layer
   13a: circuit layer
   13b: resin layer
14: first groove
15: debris
16: aperture
17: second groove

20: conveying carrier
21: frame
   21a: notch
   21b: corner cut
22: support member
   22a: adhesive side
   22b: non-adhesive side

200: plasma processing apparatus

203: vacuum chamber
203a: gas inlet
203b: gas outlet

208: dielectric member

209: antennas

210A: first high-frequency power source

210B: second high-frequency power source

211: stage

212: process gas source

213: ashing gas source

214: decompression system

215: electrode layer

216: metal layer

217: base table

218: outer peripheral portion

219: ESC electrode

220: high-frequency electrode part

221: lifting rod

222: support

223A, 223B: lifting system

224: cover
224W: window

225: coolant circulator

226: DC power source

227: coolant channel

228: controller

229: outer peripheral ring

301: laser oscillator

302: zoom expander

303: cylindrical lens

304: bend mirror

305: DOE

306: condenser lens

Rx: element region

Ry: dicing region

Rz: boundary portion

What is claimed is:

1. An element chip manufacturing method, comprising:
a step of preparing a substrate including a semiconductor layer having a first principal surface and a second principal surface and a wiring layer formed on the semiconductor layer on the first principal surface side, the substrate having a plurality of element regions and a dicing region defining the element regions;
a laser grooving step of irradiating a laser beam from the first principal surface side to the wiring layer at the dicing region, to form an aperture exposing the semiconductor layer in the dicing region; and
an individualization step of etching the semiconductor layer exposed from the aperture, with plasma, until reaching the second principal surface, to divide the substrate into a plurality of element chips having the element regions,
the laser grooving step including
a groove forming step of irradiating a first laser beam, to form a first groove exposing the semiconductor layer in the dicing region, and
a widening step of irradiating a second laser beam, with a beam center positioned outside a side wall in a width direction of the first groove formed in the groove forming step, to widen the first groove into the aperture.

2. The element chip manufacturing method according to claim 1, wherein
the groove forming step includes
a step of irradiating a third laser beam with a beam center positioned at an edge portion of the dicing region, to form a second groove as part of the first groove, and
a step of irradiating a fourth laser beam with a beam center positioned inside from the edge portion of the dicing region, to expose the semiconductor layer on a side inner than the edge portion, so that the first groove is formed.

3. The element chip manufacturing method according to claim 1, wherein in the widening step, the beam center of the second laser beam is positioned away from the side wall by ⅓ or more of a beam diameter of the second laser beam.

4. A substrate processing method for forming an aperture at a predetermined region on a substrate including a semiconductor layer having a first principal surface and a second principal surface and a wiring layer formed on the semiconductor layer on the first principal surface side, the aperture being formed to expose the semiconductor layer, the method comprising:
an irradiation step of irradiating a laser beam from the first principal surface side to the wiring layer at the predetermined region;
the irradiation step including
a groove forming step of irradiating a first laser beam, to form a first groove exposing the semiconductor layer in the predetermined region, and
a widening step of irradiating a second laser beam, with a beam center positioned outside a side wall in a width direction of the first groove formed in the groove forming step, to widen the first groove into the aperture.
